(19) United States
(12) Patent Application Publication
(10) Pub. No.: US 2013/0196459 A1
(43) Pub. Date: Aug. 1, 2013

(54) HYBRID OPTOELECTRONIC DEVICE

(71) Applicant: National Tsing Hua University, Hsinchu City (TW)

(72) Inventor: Yun-Chung Na, Hsinchu City (TW)

(73) Assignee: NATIONAL TSING HUA UNIVERSITY, Hsinchu City (TW)

(21) Appl. No.: 13/749,198

(22) Filed: Jan. 24, 2013

Related U.S. Application Data
(60) Provisional application No. 61/593,024, filed on Jan. 31, 2012.

(51) Int. Cl. H01L 31/12

(52) U.S. Cl. CPC H01L 31/125
USPC 438/24

(57) ABSTRACT

A hybrid optoelectronic device having Group III-V and Si composition on a low-cost substrate is disclosed. A photonic integrated circuit implemented by the hybrid optoelectronic device is much inexpensive and superior to those implemented by the conventional Group III-V optoelectronic device. In the hybrid optoelectronic device, a physical vapor deposition method is used to form a RMG structure with a smooth surface, and further produce a RE structure on the RMG structure. It relates a monolithic process. The wavelength and the material which attract interest can be adjusted. Thereby, the optoelectronic device can be manufactured with large yield and productivity. High optical coupling efficiency that can be offered comes from the Group III-V active device to the Si passive device (optical access). This would be beneficial to the application to the photonic integrated circuit and suitable for future development of high-performance electronic and optoelectronic devices.

### BACKGROUND OF THE INVENTION

1. Field of the Invention

The present invention relates to providing a hybrid optoelectronic device, and particularly to a device that has Group III-V and Si composition on a low-cost substrate such as Si or silicon-on-insulator (SOI) chip. More particularly, it relates to a device having a Re-epitaxy (RE) structure on a smooth surface of a rapid melt growth (RMG) structure by virtue of physical principle.

2. Description of Related Art

In the current semiconductor industry, the silicon process has been mature and widely used, and is the mainstream of the semiconductor material. However, with the physical limitations, the traditional silicon process cannot achieve the further miniature for the need of higher speed and lower cost. Group III-V semiconductor materials have been proposed in recent years due to the advantages of higher mobility and greater light absorption coefficient at optical communication wavelengths. However, Group III-V devices are generally more expensive than Si devices, because: (1) Group III-V compounds are rare elements; (2) the wafer size is small and therefore its productivity is small; and (3) the process is complicated, and therefore has low yield.

Nevertheless, devices such as lasers, light-emitting diodes, electroabsorption modulators, photodetectors (PD) and solar cells require strong electro-optical signal conversion. The direct energy bandgap and strong oscillator intensity of the group III-V elements make themselves still essential as the material for manufacturing those devices. The advantages of Group III-V elements over silicon can be used to combine the traditional silicon process and develop optoelectronic devices.

Accordingly, Shu-Lu Chen et al., “Monocrystalline GaAs and GaSb on Insulator on Bulk Si Substrates-Based on Rapid Melt Growth,” IEEE Electron Device Letters, VOL. 31, NO. 6, JUNE 2010) (as shown in FIG. 6 and FIG. 7) have proposed to form a single crystalline Group III-V material on a silicon substrate 30 having an insulator 31 by rapid melting recrystallization and using Si seed window on the insulator 31. An oxide layer 33 completely encapsulates the Group III-V material that is subject to melting/coagulation treatment so as to obtain a high-quality and very thin Group III-V film 32.

The above-described conventional technique for the group III-V epitaxial substrate of the optoelectronic device is based on metal organic chemical vapor deposition (MOCVD) and molecular beam epitaxy (MBE), and produces a RMG with rough surface which no one has any motivation to form epitaxial stacks on. Therefore, the prior art cannot meet the need for the users in actual use.

### SUMMARY OF THE INVENTION

A main purpose of this invention is to overcome the shortages in the prior art and provide a hybrid optoelectronic device which has Group III-V and Si composition on a low-cost substrate such as Si or silicon-on-insulator (SOI) chip, and a Re-epitaxy (RE) structure on a smooth surface of a rapid melt growth (RMG) structure by virtue of physical principle.

Another purpose of the invention is to provide a hybrid optoelectronic device using monolithic process which does not relate to any Group III-V chip, and the wavelength and the material which attract interest can be adjusted.

Still another purpose of the invention is to provide an optoelectronic device manufactured with large yield and productivity, in which high optical coupling efficiency comes from the Group III-V active device to the Si passive device (optical access), making this device beneficial to the application to the photonic integrated circuit and suitable for future development of high-performance electronic and optoelectronic devices.

In order to achieve the above and other objectives, the hybrid optoelectronic device of the invention includes a substrate; an insulating layer on the silicon substrate; a RMG structure on the silicon; and a RE III-V structure on the RMG structure. The RMG structure is formed by a physical vapor deposition method (Physical Vapor Deposition, PVD) to deposit amorphous germanium which is subject to rapid heating treatment for re-crystallization (Rapid-Melt Growth, RMG) so as to form a single crystalline germanium. The RE III-V structure includes a buffer layer, an active layer and a cladding layer.

In one embodiment, the silicon substrate is a silicon-on-insulator (SOI) substrate.

In one embodiment, the insulating layer is a nitride.

In one embodiment, the RMG structure further includes a protective layer which extends out from both sides of the RMG structure to form on the insulating layer and further has a thickness equal to the RMG structure.

In one embodiment, the RE III-V structure is locally formed on the RMG structure by selective growth.

In one embodiment, the RE III-V structure is patterned to form on the RMG structure by non-selective growth and etching.

In one embodiment, the buffer layer is selected from GaAs or InP.

In one embodiment, the active layer is selected from InGaAs, InAs or AlGaInAs.

In one embodiment, the cladding layer is selected from GaAs or InP.

### BRIEF DESCRIPTION OF THE DRAWINGS

FIG. 1 is a schematic, perspective view of a hybrid optoelectronic (HOE) device according to the present invention.

FIG. 2 is a schematic, cross-sectional view of a hybrid optoelectronic (HOE) device according to the present invention.

FIG. 3 is a schematic view of epitaxial patterns of RE III-V structure of a hybrid optoelectronic (HOE) device according to the present invention.

FIG. 4 is a schematic view of a distributed Bragg reflector laser structure according to the invention.

FIG. 5 is a schematic view of distributed feedback laser structure according to the present invention.

FIG. 6 is a schematic, perspective view of a conventional optoelectronic device.

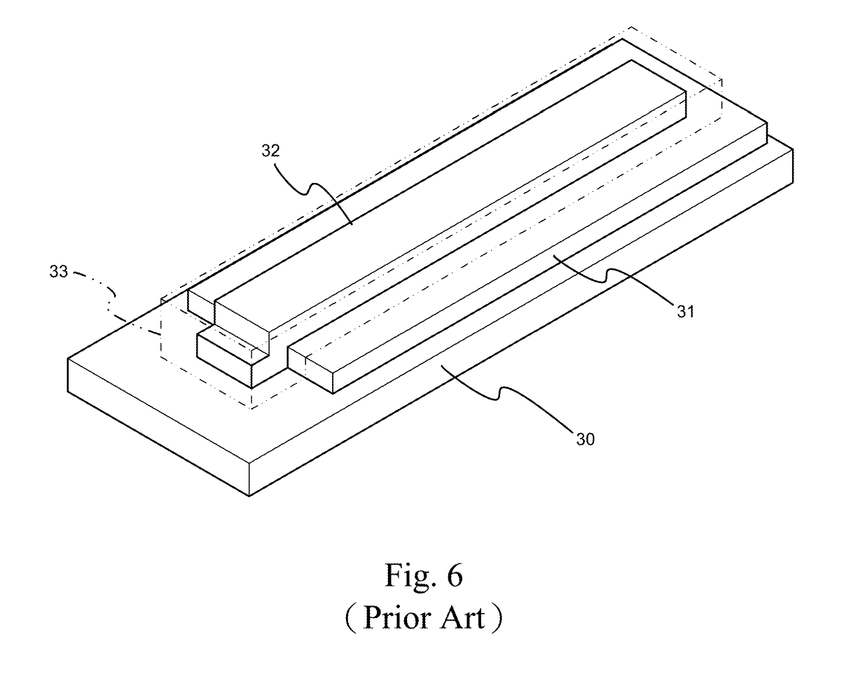

FIG. 7 is a schematic, cross-sectional view of a conventional optoelectronic device.

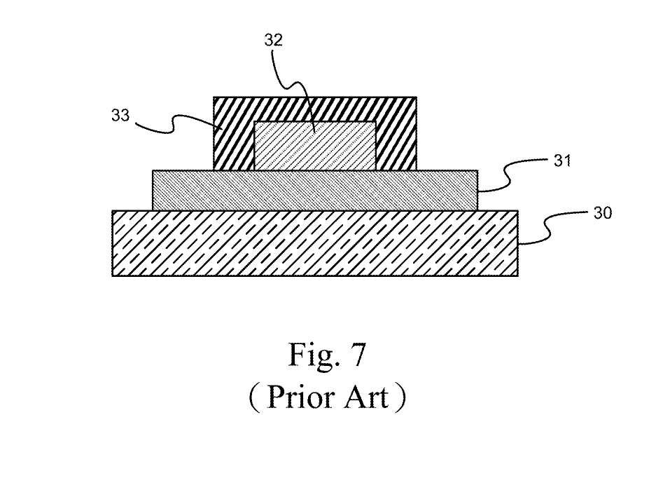

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended tables.

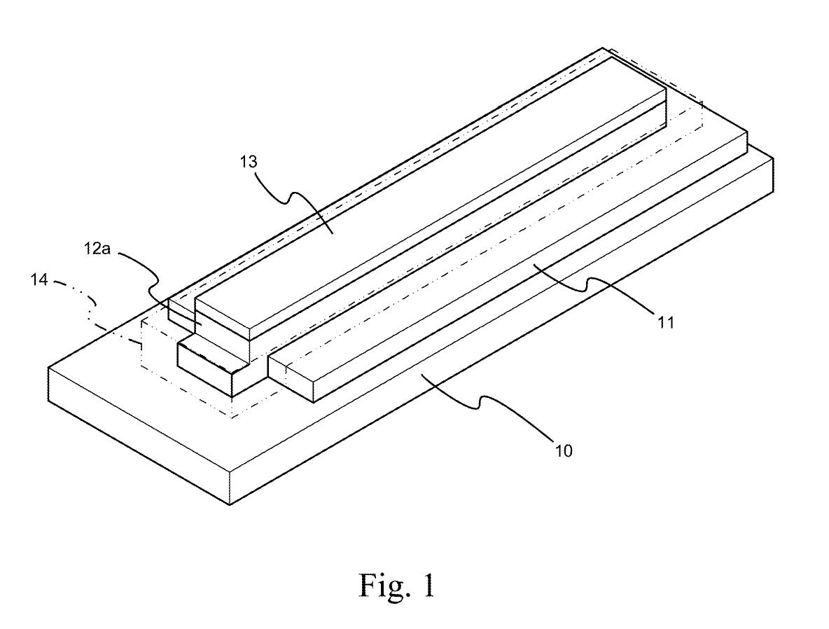

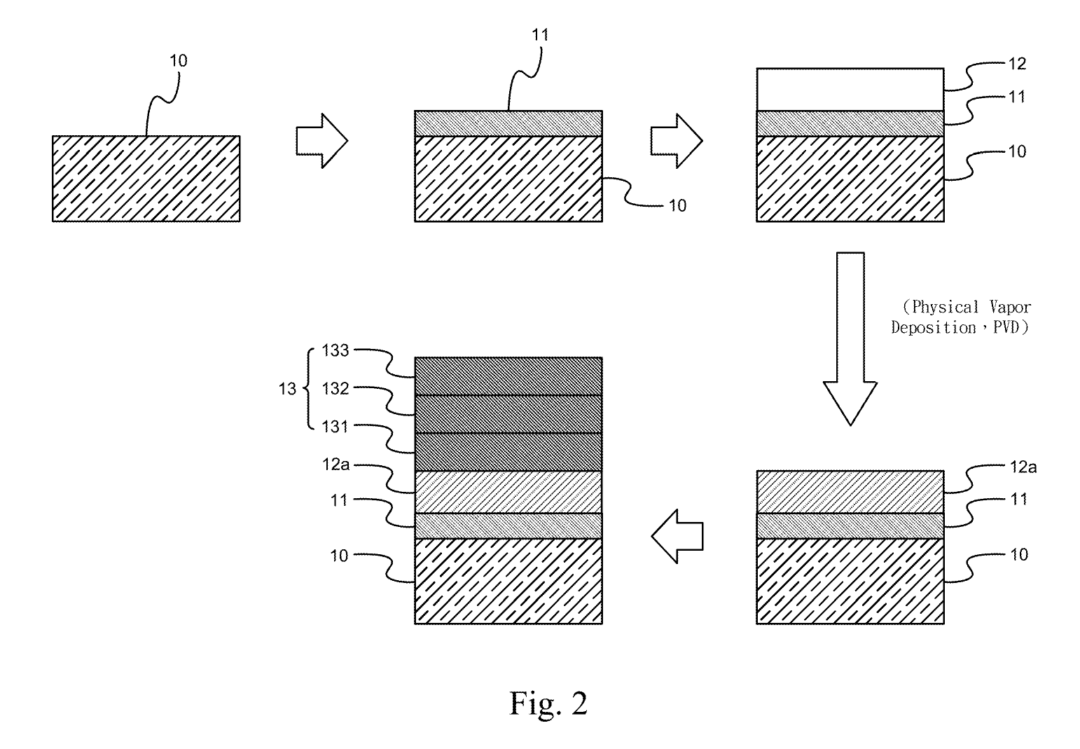

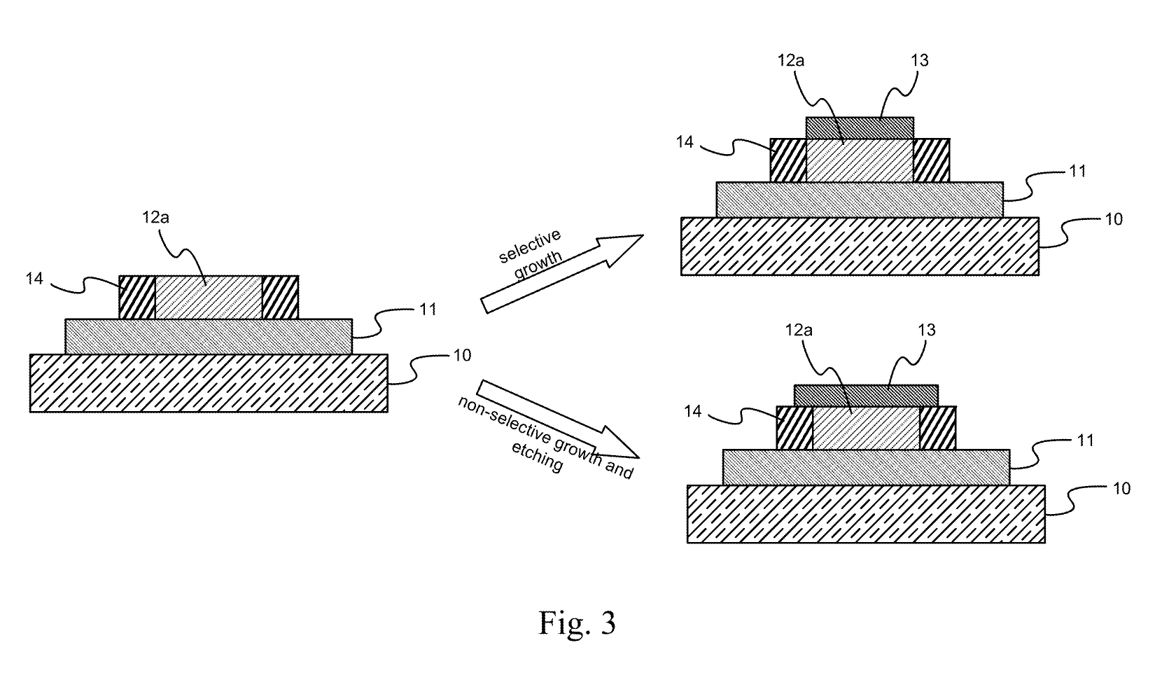

FIG. 1 is a schematic, perspective view of a hybrid optoelectronic (HOE) device according to the present invention. FIG. 2 is a schematic, cross-sectional view of a hybrid optoelectronic (HOE) device according to the present invention. FIG. 3 is a schematic view of epitaxial patterns of RE III-V structure of a hybrid optoelectronic (HOE) device according to the present invention. As shown, the hybrid optoelectronic (HOE) device according to the present invention includes a substrate 10, an insulating layer 11, a RMG structure 12a and an RE III-V structure 13.

The insulating layer 11 is formed on the substrate 10.

The RMG structure 12a is formed on the insulating layer 11. The RMG structure 12a is formed by a physical vapor deposition method (Physical Vapor Deposition (PVD) to deposit amorphous germanium which then comes to contact with the initial seed material single crystalline silicon with a series of processing steps, by rapid heating to above the melting point, and then by naturally cooling to solidify for re-crystallization (Rapid-Melt Growth, RMG) so as to form a single crystalline germanium and obtain a structure with a smooth surfaces.

The RE III-V structure 13 is formed on the RMG structure 12a, including a buffer layer 131, an active layer 132 and a cladding layer 133.

The above structure further includes a protective layer 14 which extends out from both sides of the RMG structure 12a to form on the insulating layer 11 and further has a thickness equal to the RMG structure 12a, as shown in FIG. 3

Thereby, the above structure constitutes a new hybrid optoelectronic device.

The hybrid optoelectronic device of the present invention is formed on a silicon substrate or a silicon-on-insulator (SOI) substrate. In one embodiment in which the silicon substrate 10 is exemplified for illustration, the nitride insulating layer 11 and the germanium (Ge) film 12 of group IV material have been sequentially deposited on the silicon substrate 10. When the RMG structure 12a is to be manufactured, the invention uses the physical vapor deposition method and rapidly melts the deposited amorphous germanium film 12 to be recrystallized, so that the single crystalline Group IV material on the insulating layer 11 can result from a silicon seed window and use an oxide as the protective layer 14 with having local windows. A RMG structure 12a with a smooth surface is therefore obtained. Subsequently on this smooth surface performs a re-epitaxy process (RE) to form the RE III-V structure 13 which includes gallium arsenide (GaAs) as the buffer layer, indium gallium arsenide (InGaAs) as the active layer, and GaAs as the cladding layer. The epitaxial patterns of the RE III-V structure 13 as shown in FIG. 3 can be formed locally on the RMG structure 12a by selective growth method. Alternatively, they can be patterned to form on the RMG structure and part of the protective layer 14 by non-selective growth method and etching.

In another embodiment, on the silicon substrate of the optoelectronic device of the invention can be sequentially deposited the insulating layer and a GaAs film of Group III-V material. Similarly, by virtue of the physical principle, the deposited amorphous GaAs film can be recrystallized by rapid melting so that the single crystalline Group III-V material on the insulating layer is subject to melting/condensing heat treatment through the silicon seed window to form single crystalline GaAs. A RMG structure with a smooth surface can be therefore obtained. Then a RE III-V structure including indium arsenide (InAs) as the active layer and gallium arsenide as the cladding layer is formed on the above RMG structure. Between the RMG structure and the active layer may further include a buffer layer which may be gallium arsenide.

Furthermore, in still another embodiment, on the silicon substrate of the optoelectronic device of the invention can be sequentially deposited the insulating layer and an indium phosphide (InP) film of Group III-V material. Similarly, by virtue of the physical principle, the deposited amorphous InP film can be recrystallized by rapid melting so that the single crystalline Group III-V material on the insulating layer is subject to melting/condensing heat treatment through the silicon seed window to form single crystalline InP. A RMG structure with a smooth surface can be therefore obtained. Then a RE III-V structure including aluminum gallium indium arsenide (AlGaInAs) as the active layer and indium phosphide as the cladding layer. Between the RMG structure and the active layer may further include a buffer layer which may be indium phosphide.

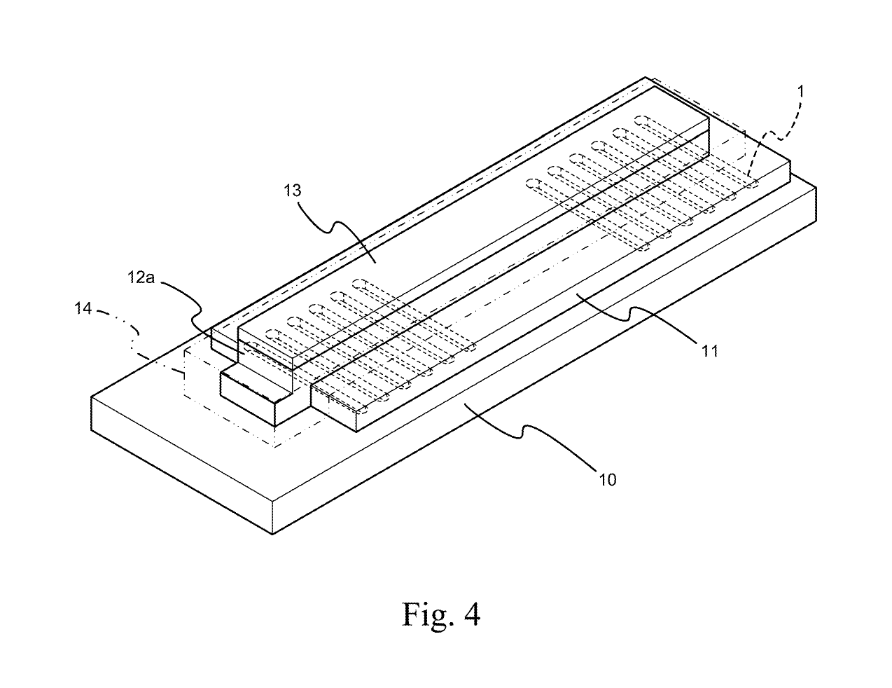

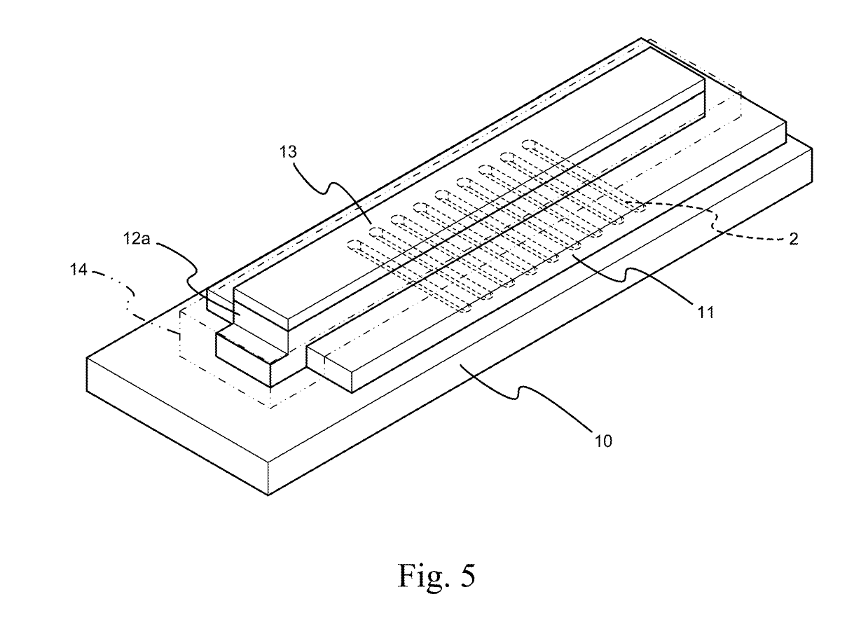

FIG. 4 is a schematic view of a distributed Bragg reflector laser structure according to the invention. FIG. 5 is a schematic view of distributed feedback laser structure according to the present invention. As shown, the hybrid optoelectronic device of the present invention can be generally applied to the electro-optical signal conversion device, such as lasers, light-emitting diodes, electrochromic absorption optical modulators, photodetectors and solar cells and so on. In one embodiment in which a laser is exemplified for illustration, FIG. 4 and FIG. 5 show two laser structures which offer the Bragg diffraction, i.e. distributed Bragg reflector (DBR) laser and distributed feedback (DFB) laser. DBR laser. A DBR laser has a grating 1 at either both sides or one side thereof in the direction of resonance cavity. The DFB laser has a grating 2 located in the whole resonance cavity.

The present invention proposes a hybrid optoelectronic device, i.e. a device which has Group III-V and Si composition on a low-cost substrate such as Si or SOI wafer and offers comparable performance with lower cost using only the Group III-V optoelectronic device. Moreover, a photonic integrated circuit implemented by the hybrid optoelectronic device is much inexpensive and superior to those implemented by the conventional Group III-V optoelectronic device. In the hybrid optoelectronic device of the present invention, the physical vapor deposition method is used to form a RMG structure with a smooth surface, and further form a RE structure on the RMG structure. The main advantages are as follows. It does not relate to any process of manufacturing Group III-V chips but instead to a monolithic process. The wavelength and the material which attract interest can be adjusted. Thereby, the optoelectronic device of the present invention can be manufactured with large yield and productivity. High optical coupling efficiency that the optoelectronic device of the present invention can offer comes from the Group III-V active device to the Si passive device (optical access). This would be beneficial to the application to the photonic integrated circuit and suitable for future development of high-performance electronic and optoelectronic devices.

In summary, the hybrid optoelectronic device of the present invention can effectively improve the drawbacks of the prior art by using the physical vapor deposition method to manufacturing the RMG structure with a smooth surface. A RE structure may be further formed on the RMG structure. It does not relate to any process of manufacturing Group III-V chips but instead to a monolithic process. The wavelength and the material which attract interest can be adjusted. Thereby, the optoelectronic device of the present invention can be manufactured with large yield and productivity. High optical coupling efficiency that the optoelectronic device of the present invention can offer comes from the Group III-V active device to the Si passive device (optical access). This would be beneficial to the application to the photonic integrated circuit. This makes the invention more progressive and more practical in use which complies with the patent law.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A process of manufacturing a hybrid optoelectronic (HOE) device
(A) providing a silicon substrate;
(B) depositing an insulating layer on the silicon substrate;
(C) depositing a Group IV Ge film on the insulating film;
(D) using a physical vapor deposition method (Physical Vapor Deposition (PVD) to deposit amorphous germanium which comes to contact with the initial material single crystalline silicon, rapid heating to above the melting point, and then naturally cooling to solidify for re-crystallization (Rapid-Melt Growth, RMG) so as to form a single crystalline germanium and obtain a RMG structure with a smooth surface; and
(E)performing on the RMG structure a re-epitaxy process (RE) to form a RE III-V structure which comprises gallium arsenide (GaAs) as a buffer layer, indium gallium arsenide (InGaAs) as an active layer, and GaAs as a cladding layer.

2. The process of claim 1, wherein the silicon substrate is a silicon-on-insulator (SOI) substrate.

3. The process of claim 1, wherein the insulating layer is a nitride.

4. The process of claim 1, wherein the RE III-V structure is locally formed on the RMG structure by selective growth.

5. The process of claim 1, wherein the RE III-V structure is patterned to form on the RMG structure by non-selective growth and etching.

6. The process of claim 1, wherein the buffer layer is selected from GaAs or InP.

7. The process of claim 1, wherein the active layer is selected from InGaAs, InAs or AlGaInAs.

8. The process of claim 1, wherein the cladding layer is selected from GaAs or InP.
